(19) United States
(12) Patent Application Publication
(10) Pub. No.: US 2017/0088742 A1
(43) Pub. Date: Mar. 30, 2017

(54) USE OF A COATING COMPOSITION TO COAT THE BACKING FILM OF A PHOTOVOLTAIC MODULE, AND PHOTOVOLTAIC MODULE

(71) Applicant: BASF Coatings GmbH, Muenster (DE)

(72) Inventors: Jan-Bernd KUES, Muenster (DE); Simone KUESENER, Ascheberg (DE); Sebastian RENNER, Muenster (DE)

(73) Assignee: BASF Coatings GmbH, Muenster (DE)

(21) Appl. No.: 15/310,829

(22) PCT Filed: Apr. 23, 2015
(86) PCT No.: PCT/EP2015/058762

§ 371 Date: Nov. 14, 2016

(30) Foreign Application Priority Data
May 16, 2014 (EP) 14168682.4

(51) Int. Cl. C09D 133/14; H01L 31/048; H01L 31/049; H01L 31/18

(52) U.S. Cl. CPC C09D 133/14; H01L 31/1876; H01L 31/0481; H01L 31/049; C08K 2003/2241

(57) ABSTRACT

The invention relates to the use of a coating composition to coat the backing film of a photovoltaic module. The coating composition is a 2-component coating composition comprising a resin component (A) and a crosslinker component (B). The resin component (A) comprises
a1) a polyester having a hydroxyl number of 60 to 300 mg KOH/g and a glass transition temperature T_{g} of −65° C. to 50° C.,
a2) a poly(meth)acrylate (co)polymer having a hydroxyl number of 50 to 250 mg KOH/g and a glass transition temperature of −65° C. to 50° C.,
a3) pigments and/or fillers,
a4) coating additives,
a5) optionally a light stabilizer,
a6) a phosphoric ester, and
a7) organic solvent.

The crosslinker component (B) comprises
b1) a polyisocyanate and
b2) optionally organic solvent.

The invention also relates to a corresponding photovoltaic module.

The present invention relates to the use of a coating composition for coating the backing film of a photovoltaic module, and to a photovoltaic module having a coated backing film.

Photovoltaic modules generally have a glass cover layer on their front. Beneath the cover layer there is an elastic layer in which solar cells are embedded. To protect against mechanical damage and to protect against weathering effects, the back of the photovoltaic module finishes with a plate or a backing film. At the sides, the layer system described is closed off with a frame, which gives the module the necessary mechanical stability and also prevents penetration of moisture or dust.

The backing film, also referred to as barrier film, may consist of a multi-ply laminate with, for example, a polyethylene terephthalate core. The core is laminated on either side with a film, consisting of polyvinyl fluoride or polyvinylidene fluoride, for example. Also possible is the use of a single-ply, unlaminated film as backing film. In this case the film in question may be a polyethylene terephthalate film.

To enhance the protection from weathering it is usual to coat the single-ply or multi-ply backing film, at least on the side which lies on the outside in the completed module, with a coating composition.

Known from international patent applications WO 2013/173629 A1 is a backing film for a photovoltaic module that has a coating on its outside, this coating comprising a fluoropolymer resin and a crosslinking agent. The patent application does include acrylate resins and polyurethanes as suitable polymer resins. No details of the composition of such resins are given, however. The resins are preferably fluoropolymer resins, which to improve the adhesion include at least one acid group. Resins containing fluorine impose a burden on the environment in their preparation, in their processing and especially in their disposal.

It is an object of the present invention to specify an eco-friendly alternative to fluorine-containing resins that nevertheless results in good weathering stability and in effective adhesion to the film base.

This object is achieved in accordance with the invention through the use of a coating composition for coating the backing film of a photovoltaic module, the coating composition being a 2-component coating composition comprising a resin component (A) and a crosslinker component (B), the resin component (A) comprising

a1) 3 to 20 wt %, based on the nonvolatile fraction of the resin component, of a polyester having a hydroxyl number of 60 to 300 mg KOH/g and a glass transition temperature T_{g} of −65° C. to 50° C.,

a2) 10 to 40 wt %, based on the nonvolatile fraction of the resin component, of a poly(meth)acrylate (co)polymer having a hydroxyl number of 50 to 250 mg KOH/g and a glass transition temperature of −65° C. to 50° C.,

a3) 40 to 86 wt %, based on the nonvolatile fraction of the resin component, of pigment and/or fillers,

a4) 0.1 to 10 wt %, based on the nonvolatile fraction of the resin component, of coating additives,

a5) 0 to 6 wt %, based on the nonvolatile fraction of the resin component, of a light stabilizer,

a6) 0.01 to 1 wt %, based on the nonvolatile fraction of the resin component, of phosphoric esters of the general formula

PO (OR)ₙ (OH)ₘ,

in which
n=1-3,
m=0-2, and
n+m=3,

R is selected from the group consisting of straight-chain or branched alkyl radicals having 1 to 16 carbon atoms, which may be substituted by aromatic radicals and/or may contain ether oxygen atoms (—O—), and aromatic radicals, which may be substituted by alkyl radicals having 1 to 6 carbon atoms, where if n=2 or 3 the radicals R may be identical or different, the sum total of constituents a1) to a6) being 100 wt %, and

a7) 20 to 50 wt %, based on the total weight of the resin component (A), of organic solvent, and

the crosslinker component (B)

b1) 30 to 100 wt % polyisocyanate and

b2) 0 to 70 wt % of organic solvent, the sum total of the constituents b1) and b2) being 100 wt %. The hydroxyl number is determined according to DIN 53240-2 and the glass transition temperature Tg by means of dynamic scanning calorimetry DSC according to DIN 53765. The nonvolatile fraction (NVF) is determined according to DIN EN ISO 3251 under the following test conditions: test duration 60 min, test temperature 150° C. and initial mass 1.5 g+/−0.1 g.

The coating composition used for the coating of the backing film is known per se. It is used, for example, in automotive refinishing and in original (OEM) finishing, and also in the refinishing of trucks and construction machinery. It was surprising that this coating composition is suitable for the coating of backing films of photovoltaic modules and results in high weathering resistance and effective adhesion to the films.

Suitable phosphoric esters are, for example, dibutyl hydrogenphosphate, butyl dihydrogenphosphate, 2-ethyl-hexyl dihydrogenphosphate, phenyl dihydrogenphosphate, benzyl dihydrogenphosphate, 2-ethoxybutyl dihydrogenphosphate and the like. Dialkyl hydrogenphosphates and alkyl dihydrogenphosphates are preferred. Mixtures of phosphoric esters may also be used.

Advantageous embodiments of the invention are apparent from the dependent claims.

The organic solvents present in the resin component (A) and in the crosslinker component (B) are, advantageously, acetates, such as butyl acetate or ethyl acetate, or aromatics such as solvent naphtha or toluene.

The backing film consists advantageously of polyethylene terephthalate, polyvinyl fluoride, or polyvinylidene fluoride.

The outside of the backing film is advantageously coated. It is also possible, however, to coat the outside and the inside of the backing film.

The wet-film thickness of the coating is advantageously 10 to 40 μm.

The coating composition is applied advantageously by spraying, rolling, or knife coating to the backing film.

Following the application of the coating composition, it is cured advantageously at a temperature of 110 to 150° C. within a period of 20 to 40 s.

The invention also relates to a photovoltaic module having a coated backing film, the coating having been produced by application and curing of a 2-component coating composition comprising a resin component (A) and a crosslinker component (B), the resin component (A) comprising

a1) 3 to 20 wt %, based on the nonvolatile fraction of the resin component, of a polyester having a hydroxyl number of 60 to 300 mg KOH/g and a glass transition temperature T_{g} of −65° C. to 50° C.,

a2) 10 to 40 wt %, based on the nonvolatile fraction of the resin component, of a poly(meth)acrylate (co)polymer having a hydroxyl number of 50 to 250 mg KOH/g and a glass transition temperature of −65° C. to 50° C.,

a3) 40 to 86 wt %, based on the nonvolatile fraction of the resin component, of pigment and/or fillers,

a4) 0.1 to 10 wt %, based on the nonvolatile fraction of the resin component, of coating additives,

a5) 0 to 6 wt %, based on the nonvolatile fraction of the resin component, of a light stabilizer,

a6) 0.01 to 1 wt %, based on the nonvolatile fraction of the resin component, of phosphoric esters of the general formula

PO (OR)ₙ (OH)ₘ,

in which
n=1-3,
m=0-2, and
n+m=3,

R is selected from the group consisting of straight-chain or branched alkyl radicals having 1 to 16 carbon atoms, which may be substituted by aromatic radicals and/or may contain ether oxygen atoms (—O—), and aromatic radicals, which may be substituted by alkyl radicals having 1 to 6 carbon atoms, where if n=2 or 3 the radicals R may be identical or different, the sum total of constituents a1) to a6) being 100 wt %, and

a7) 20 to 50 wt %, based on the total weight of the resin component (A), of organic solvent, and the crosslinker component (B)

b1) 30 to 100 wt % polyisocyanate and

b2) 0 to 70 wt % of organic solvent, the sum total of the constituents b1) and b2) being 100 wt %.

Advantageous embodiments of the photovoltaic module are apparent from the dependent claims.

The backing film consists advantageously of polyethylene terephthalate.

Advantageously at least the outside of the backing film is coated. It is also possible, however, for the outside and the inside of the backing film to be coated.

The dry-film thickness of the coating is advantageously 20 to 35 μm.

The invention is illustrated in more detail below, using working examples.

Preparation Example for Resin Component A:

The component A can be manufactured by the following preparation method. This method consists of a number of steps.

In the first step, the binders, optionally a portion of the solvents, and the entire pulverulent pigments are processed to millbase in a suitable batching vessel. For this processing, first the two binders, the acrylate, and the polyester are charged to a drum. If the viscosity of the binders makes it necessary to do so, a portion of the solvent can be added, in order to prevent excessive introduction of air during stirring. The mixture is stirred for about 10 min with slight vortexing, using an inclined blade stirrer, until the resulting mixture is homogeneous and has no streaks or the like.

Thereafter the silica is added cautiously with stirring. When the components have been wetted, the mixture can be dissolver-treated for about 30 minutes until the paste is free from lumps. The temperature of the millbase here must not exceed 50° C.

Subsequently, the remainder of the pulverulent pigments are added, with slow stirring. The mixture, which has a high viscosity, is dissolver-treated again until the resulting paste is homogenous to the eye. In order to prevent a temperature increase above 50° C., the batch must be cooled as and when necessary.

Toward the end of the dispersing time, the remaining solvent is added, to dilute the millbase batch appropriately for dispersing by circulation in an agitator mill. In the mill, the millbase is circulated until a fineness of grind of 10-15 μm is attained. Here as well, it may be necessary to attach a water cooling facility. The fineness of grind is determined using a Hegmann 50 gage.

The discharged millbase can then be made up with the appropriate weight % of additives. These additives are likewise added with stirring.

Preparation of the Coating Composition

Component A is adjusted by addition of component B (HDI trimer) and the solvent for adjusting the viscosity for processability. The amount of isocyanate selected should be such as to enable ideally the attainment of 20% overcrosslinking. The completed 2-component mixture has a pot life of >5 hours. This means that no earlier than after 5 hours, depending on the amount of solvent added, from the moment of mixing, is a doubling in the flow time from a DIN 4 cup observable at 23° C. The coating composition, consequently, is fundamentally suitable for application in a roll-to-roll process. The corresponding parameters must always be determined on the specific line.

To produce a test specimen for the mechano-technological tests, ambient conditions tests, and weathering, the coating composition is knife-coated onto the appropriate substrate—PET, for example. The knife coater must be selected so as to achieve a dry-film thickness of between 10 and 15 μm, depending on the solids. Following paint application, the test specimen is baked immediately, without flashing, in a convection oven at 150° C. for 30 seconds.

TABLE 1
composition of the coating materials

| | | Example I | | Example II | |
|---|---|---|---|---|---|
| | | Initial | NVF-m | Initial | NVF-m |
| Item | Commercial product | mass [g] | [g] | mass [g] | [g] |

Component A

| | | | | | |
|---|---|---|---|---|---|
| 1 | Macrynal SM 685 (OH | 17 | 9.35 | 36.8 | 20.24 |
| | number 77-93, OH | | | | |
| | content (NVF) 2.6%, | | | | |
| | 55% in butyl acetate as | | | | |
| | per TDS) | | | | |
| 2 | Desmophen 670 (OH | 5 | 4 | 5.1 | 4.08 |
| | number 115, OH content | | | | |
| | (NVF) 3.5%, 80% | | | | |
| | fraction in butyl acetate | | | | |
| | as per TDS) | | | | |
| 3 | Talco HM1 | 12.5 | 12.5 | 6.3 | 6.3 |
| 5 | Zinkphosphat PZ 20 | 2.6 | 2.6 | 1.3 | 1.3 |
| 6 | Blanc Fixe PLV.HD 80 | 16.4 | 16.4 | 8.2 | 8.2 |
| 7 | Tiona 595 | 29.5 | 29.5 | 28.3 | 28.3 |
| 8 | Baysilon OL 17 | 0.2 | 0.17 | 0.2 | 0.2 |
| 9 | Duraphos BAP | 0.1 | 0.1 | 0.1 | 0.1 |
| 10 | Aerosil 200 | 0.6 | 0.6 | 0.3 | 0.3 |
| 12 | Butyl acetate | 16.1 | 0 | 13.4 | 0 |

Component B

| | | | | | |
|---|---|---|---|---|---|
| 13 | Desmodur N3600 56% in | 8.9 | 5.0 | 15.27 | 8.4 |
| | butyl acetate | | | | |
| | sum total | 108.9 | 80.204 | 115.27 | 77.42 |

| | |
|---|---|
| Macrynal SM 685: | OH-functional acrylate resin |
| Desmophen 670: | OH-functional polyester |
| Talco HM1: | talc |
| Zinkphosphat PZ 20: | zinc phosphate |
| Blanc Fixe PLV.HD 80: | barium sulfate |
| Tiona 595: | titanium dioxide (rutile type) |
| Baysilon OL 17: | polyether-modified |
| | polysiloxane |
| Duraphos BAP: | mixture of dibutyl |
| | hydrogenphosphate (48-57%) and |
| | butyl dihydrogenphosphate (40- |
| | 48%) |
| Aerosil 200: | hydrophilic fumed silica |
| Desmodur N3600: | polyfunctional aliphatic |
| | polyisocyanate resin based on |
| | hexamethylene diisocyanate |

Testing of the Coating Composition

After cooling, freedom from tack is verified by the Zapon Tack Test (ZTT). For this test, a strip of aluminum with a thickness of about 0.5 mm, a width of 2.5 cm, and a length of about 11 cm is bent in a 110° angle so as to produce an area of 2.5×2.5 cm. The long side of the metal is bent by about 15° for a further 2.5 cm in such a way that the metal is just held in balance by a 5 g weight placed centrally on the square area. For the measurement of the freedom from tack by the ZTT method, the bent metal, directly after the test specimen has cooled, is placed on the paint film and loaded with a 100 g weight for 30 seconds. After the weight has been removed, the paint is considered tack-free if the metal angle falls over within 5 seconds. The baked paint system (variants A and B) is tack-free after 30 seconds at 150° C.

In addition, a blocking test was carried out. For this purpose, a further PET film was placed all over the surface and loaded briefly (˜10 seconds) with a 2 kg weight. If the applied film could be removed thereafter without any resistance, the drying was scored as OK. According to this test, the drying of the paint system (variants A and B) is OK.

For further tests, the test specimen is aged in a convection oven at 150° C. for 20 minutes. This accelerates the process of aftercrosslinking, which would occur in the case of the storage of the applied rolls prior to further processing.

The test specimen is thereafter subjected to a boiling test. For this purpose, fully demineralized water in a stainless steel bowl is brought to boiling on a hob plate, i.e., to a test temperature of 100° C., and the test specimen is introduced for two 8-hour cycles so that it is completely under water. After each cycle, the test specimen is removed, dried, and inspected.

There must be no visible changes to the paint surface. This is followed by a DIN ISO 2409 cross-cut procedure, directly after exposure and again after 1 hour of regeneration. The lattice spacing is set at 1 mm in line with the plastic substrate and the low paint film layer thickness. The cross-cut classification is to be <2. Testing of variants A and B produced a cross-cut classification of 0 after each cycle, both directly after exposure, and after 1 hour of regeneration. The inspection also yields no adverse comments.

Following the successful quick test, long-term ambient conditions tests are conducted, firstly in the form of a constant condensation condition (CC) test according to DIN EN ISO 6270-2. The test specimen is stored for 240 hours at 40° C.+/− and at a relative humidity of 100%, with condensation being made to form on the test specimen.

Secondly, the test specimen is stored in an individually adjustable conditioning cabinet. The parameters selected, 504 hours at 85° C. and 85% relative humidity, are intended to approximate to the conditions of the DIN EN ISO 60068 damp heat test required in the photovoltaics industry.

After exposure on both sets of conditions, the paint film is tested in the same way as after the boiling test: verification of adhesion by cross-cut directly after exposure and after 1 hour of regeneration (target cross-cut classification <2). The paint film is also inspected, and here again must not show any visual changes. After both tests, variants A and B show no changes at all after inspection. Both directly after exposure and after 1 hour of regeneration, the cross-cut classifications were 0.

Lastly, the weathering stability was tested in accordance with SAE J2527_04 in the WOM-CAM. The total test duration is 3000 hours. Evaluation takes place after each 1000 hours by means of colorimetric measurement relative to the unexposed standard, and inspection of the surface. The total color difference after 3000 hours by comparison with the unexposed sample has a mDE* of 1.0.

1: A method for coating the backing film of a photovoltaic module, the method comprising:
coating a backing film with a coating composition to form a coating on the backing film,
wherein the coating composition is a 2-component coating composition comprising:
a resin component (A); and
a crosslinker component (B),
the resin component (A) comprising:
a1) 3 to 20 wt %, based on the nonvolatile fraction of the resin component, of a polyester having a hydroxyl number of 60 to 300 mg KOH/g and a glass transition temperature T_{g} of −65° C. to 50° C.,
a2) 10 to 40 wt %, based on the nonvolatile fraction of the resin component, of a poly(meth)acrylate (co)polymer having a hydroxyl number of 50 to 250 mg KOH/g and a glass transition temperature of −65° C. to 50° C.,
a3) 40 to 86 wt %, based on the nonvolatile fraction of the resin component, of pigment and/or fillers a filler,
a4) 0.1 to 10 wt %, based on the nonvolatile fraction of the resin component, of a coating additives additive,
a5) 0 to 6 wt %, based on the nonvolatile fraction of the resin component, of a light stabilizer,
a6) 0.01 to 1 wt %, based on the nonvolatile fraction of the resin component, of phosphoric esters of the general formula
PO (OR)ₙ (OH)ₘ,
in which
n=1-3,
m=0-2, and
n+m=3,
R is selected from the group consisting of straight-chain or branched alkyl radicals having 1 to 16 carbon atoms, which may be substituted by aromatic radicals and/or may contain ether oxygen atoms (—O—), and aromatic radicals, which may be substituted by alkyl radicals having 1 to 6 carbon atoms,
the sum total of constituents a1) to a6) being 100 wt %, and
a7) 20 to 50 wt %, based on the total weight of the resin component (A), of organic solvent, and
the crosslinker component (B) comprising:
b1) 30 to 100 wt % polyisocyanate, and
b2) 0 to 70 wt % of organic solvent,
the sum total of the constituents b1) and b2) being 100 wt %.

2: The method as claimed in claim 1, wherein the organic solvent present in the resin component (A) and in the crosslinker component (B) is an acetate compound or an aromatic compound.

3: The method as claimed in claim 1, wherein the backing film comprises at least one of polyethylene terephthalate, polyvinyl fluoride, and polyvinylidene fluoride.

4: The method as claimed in claim 1, wherein the an outside of the backing film is coated.

5: The method as claimed in claim 1, wherein the an outside and the an inside of the backing film are coated.

6: The method as claimed in claim 1, wherein the a wet-film thickness of the coating is 10 to 40 μm.

7: The method as claimed in claim 1, wherein said coating is carried out by spraying, by rolling, or knife coating the coating composition to the backing film.

8: The method as claimed in claim 1, further comprising:
curing the coating composition at a temperature of from 110° C. to 150° C. within a time period of 20 to 40 seconds.

9: A photovoltaic module having comprising a coated backing film, wherein the coating of the coated backing film is a cured
coating composition, wherein
the coating composition is a 2-component coating composition comprising:
a resin component (A); and
a crosslinker component (B),
the resin component (A) comprising:
a1) 3 to 20 wt %, based on the nonvolatile fraction of the resin component, of a polyester having a hydroxyl number of 60 to 300 mg KOH/g and a glass transition temperature T_{g} of −65° C. to 50° C.,
a2) 10 to 40 wt %, based on the nonvolatile fraction of the resin component, of a poly(meth)acrylate (co)polymer having a hydroxyl number of 50 to 250 mg KOH/g and a glass transition temperature of −65° C. to 50° C.,
a3) 40 to 86 wt %, based on the nonvolatile fraction of the resin component, of pigment and/or a filler,
a4) 0.1 to 10 wt %, based on the nonvolatile fraction of the resin component, of a coating additive,
a5) 0 to 6 wt %, based on the nonvolatile fraction of the resin component, of a light stabilizer,
a6) 0.01 to 1 wt %, based on the nonvolatile fraction of the resin component, of phosphoric esters of the general formula
PO (OR)ₙ (OH)ₘ,
in which
n=1-3,
m=0-2, and
n+m=3,
R is selected from the group consisting of straight-chain or branched alkyl radicals having 1 to 16 carbon atoms, which may be substituted by aromatic radicals and/or may contain ether oxygen atoms (—O—), and aromatic radicals, which may be substituted by alkyl radicals having 1 to 6 carbon atoms, the sum total of constituents a1) to a6) being 100 wt %, and
a7) 20 to 50 wt %, based on the total weight of the resin component (A), of organic solvent, and
the crosslinker component (B) comprising:
b1) 30 to 100 wt % polyisocyanate; and
b2) 0 to 70 wt % of organic solvent, the sum total of the constituents b 1) and b2) being 100 wt %.

10: The photovoltaic module as claimed in claim 9, wherein the backing film comprises at least one of polyethylene terephthalate, polyvinyl fluoride, or polyvinylidene fluoride.

11: The photovoltaic module as claimed in claim 9, wherein an outside of the backing film is coated.

12: The photovoltaic module as claimed in claim 9, wherein an outside and an inside of the backing film are coated.

13: The photovoltaic module as claimed in claim 9, wherein a dry-film thickness of the coating is 20 to 35 μm.
